(19) United States
(12) Patent Application Publication
(10) Pub. No.: US 2026/0182292 A1
(43) Pub. Date: Jun. 25, 2026

(54) SUBSTRATE PROCESSING APPARATUS AND GAS PRESSURE CONTROL METHOD USED THEREIN

(71) Applicant: HPSP Co., Ltd., Hwaseong-si (KR)

(72) Inventor: John Christopher Garrett, Sunnyvale, CA (US)

(21) Appl. No.: 19/413,220

(22) Filed: Dec. 9, 2025

Related U.S. Application Data
(60) Provisional application No. 63/738,201, filed on Dec. 23, 2024.

(51) Int. Cl. H10P 72/00; F27B 17/00; F27D 3/00; F27D 7/06; G05D 7/06

(52) U.S. Cl. CPC H10P 72/0402; F27B 17/0025; F27D 3/0084; F27D 7/06; G05D 7/0635

(57) ABSTRACT

A substrate processing apparatus and a gas pressure control method used therein are disclosed. The substrate processing apparatus may include a process chamber, a load-lock chamber, and an exhaust module. The process chamber may accommodate a boat for loading a substrate. The load-lock chamber may be formed to accommodate the boat moved from the process chamber. The exhaust module may include a main exhaust line connected to the load-lock chamber to exhaust a load-lock gas present in the load-lock chamber, and a sub-exhaust line connected to the load-lock chamber and configured to exhaust the load-lock gas at a lower flow rate than the main exhaust line.

### BACKGROUND

### 1. Field

The present disclosure relates to a substrate processing apparatus and a gas pressure control method used therein

### 2. Description of Related Art

In general, during a manufacturing process of semiconductor devices, various processing operations are performed on semiconductor substrates. Examples of such processing include oxidation, nitridation, ion implantation, and deposition processes. There are also hydrogen or deuterium heat treatment processes for improving interface characteristics of the semiconductor devices.

The processing is performed by introducing substrates and gas into a reaction space of a process chamber. The substrates can be introduced into the reaction space while loaded on a boat through a load-lock chamber, or withdrawn from the reaction space. The pressure of gas in the load-lock chamber can be controlled differently depending on factors such as whether the boat is present in the load-lock chamber. The pressure can generally be switched between vacuum and pressures above atmospheric pressure. To this end, a vacuum pump is connected to an exhaust line of the load-lock chamber, and venting gas is injected into the load-lock chamber through a venting line.

To exhaust gas present in the load-lock chamber through an exhaust line to achieve a set pressure, a control module sends a signal to a flow control valve to change an opening degree of the flow control valve installed in the exhaust line. As the flow control valve changes an opening degree in response to the signal, the gas in the load-lock chamber can be controlled to the set pressure.

### SUMMARY

According to the present inventor's findings, in a process of controlling a gas pressure within a load-lock chamber to a set pressure, the gas pressure may undergo large fluctuations. Specifically, the gas pressure may overshoot or undershoot the set pressure. Such fluctuations may be caused, for example, by a delay in a response of a flow control valve to a control signal of a control module.

In view of these problems, an object of the present disclosure is to provide a substrate processing apparatus and a gas pressure control method used therein that enables stable control of the gas pressure within the load-lock chamber.

The objects to be solved by the present disclosure are not limited to the above-mentioned objects, and other objects not mentioned can be clearly understood by those skilled in the art from the following description.

According to an aspect of the present disclosure, a substrate processing apparatus may include: a process chamber accommodating a boat for loading a substrate; a load-lock chamber configured to accommodate a boat moved from the process chamber; and an exhaust module having a main exhaust line connected to the load-lock chamber to exhaust a load-lock gas present in the load-lock chamber, and a sub-exhaust line connected to the load-lock chamber and configured to exhaust the load-lock gas at a lower flow rate than the main exhaust line.

According to an embodiment, an inner diameter of the sub-exhaust line may be half or less than an inner diameter of the main exhaust line.

According to an embodiment, the exhaust module may further include a main flow control valve installed in the main exhaust line, and further include a control module configured to adjust an opening degree of the main flow control valve by controlling the main flow control valve, and the control module may be configured to adjust the opening degree while the load-lock gas is exhausted through the sub-exhaust line.

According to an embodiment, the control module may be configured to control the main flow control valve to allow the load-lock gas to be exhausted through the main exhaust line and the sub-exhaust line in parallel.

According to an embodiment, the exhaust module may further include a sub-flow control valve installed in the sub-exhaust line, and an opening degree of the sub-flow control valve may be maintained at a set value.

According to an embodiment, the sub-exhaust line may be connected to any one selected from the group consisting of the main exhaust line, a case of a gas box for supplying process gas to the process chamber, and a box exhaust line connected to the case for exhausting box gas within the case.

According to an embodiment, the sub-exhaust line may include a first sub-line connected to either the main exhaust line or the box exhaust line, and a second sub-line connected to the case, and the exhaust module may further include a first sub-valve installed in the first sub-line, and a second sub-valve installed in the second sub-line, and further include a control module configured to control the first sub-valve and the second sub-valve.

According to an embodiment, the control module may be configured to selectively open either the first sub-valve or the second sub-valve.

According to an embodiment, the control module may be configured to open the first sub-valve when the boat is located within the load-lock chamber, and open the second sub-valve when the boat is located within the process chamber.

According to another aspect of the present disclosure, a gas pressure control method in a substrate processing apparatus may include: controlling, to control a pressure of a load-lock gas present in a load-lock chamber accommodating a boat moved from a process chamber, an opening degree of a main flow control valve installed in a main exhaust line connected to the load-lock chamber; and allowing the load-lock gas to be exhausted at a lower flow rate than the main exhaust line through a sub-exhaust line connected to the load-lock chamber during the adjustment of the opening degree of the main flow control valve.

According to an embodiment, the allowing of the load-lock gas to be exhausted at the lower flow rate than the main exhaust line through the sub-exhaust line connected to the load-lock chamber during the adjustment of the opening degree of the main flow control valve may include allowing one mode of the following to be performed: a first mode to allow the load-lock gas to be exhausted through either the main exhaust line or a box exhaust line of a gas box for supplying a process gas to the process chamber, and a second mode to allow the load-lock gas to be exhausted through a case of the gas box.

According to an embodiment, the first mode may be performed when the boat is located within the load-lock chamber, and the second mode may be performed when the boat is located within the process chamber.

According to the substrate processing apparatus and the gas pressure control method used therein according to the present disclosure configured as described above, both a main exhaust line and a sub-exhaust line are connected to a load-lock chamber that accommodates a boat of a process chamber, and since the configuration allows a small amount of load-lock gas to be exhausted through the sub-exhaust line in addition to the main exhaust line, fluctuations in the load-lock gas pressure during exhaust by the main exhaust line can be minimized and the pressure of the load-lock gas can be managed more stably.

The effects of the present disclosure are not limited to the above-described effects, and should be understood to include all effects that can be inferred from the detailed description of the present disclosure or the configuration of the present disclosure as set forth in the claims.

### BRIEF DESCRIPTION OF DRAWINGS

FIG. 1 is a conceptual diagram illustrating a substrate processing apparatus according to an embodiment of the present disclosure.

FIG. 2 is a conceptual diagram illustrating a substrate processing apparatus according to a modified example of the substrate processing apparatus of FIG. 1.

FIG. 3 is a conceptual diagram illustrating a substrate processing apparatus according to another embodiment of the present disclosure.

FIG. 4 is a block diagram for describing a control operation of the substrate processing apparatus of FIG. 3.

FIG. 5 is a flowchart showing a gas pressure control method in a substrate processing apparatus according to yet another embodiment of the present disclosure.

FIG. 6 is a flowchart showing specific contents of one step of FIG. 5.

### DETAILED DESCRIPTION

Hereinafter, a preferred embodiment of the present disclosure will be described in detail with reference to the accompanying drawings.

However, the present disclosure is not limited to an embodiment disclosed below but various changes may be made and the present disclosure may be implemented in various different forms. The embodiment is merely provided to make the disclosure of the present disclosure complete and to fully inform those skilled in the art of the scope of the present disclosure. Therefore, it should be understood that the present disclosure is not limited to the embodiments disclosed below, but includes all modifications, equivalents, and substitutions that are included in the technical spirit and scope of the present disclosure, as well as substitutions or additions of the configurations of any one embodiment and the configurations of other embodiments.

It is to be understood that the accompanying drawings are just used for easily understanding the exemplary embodiments disclosed in this specification and a technical spirit disclosed in this specification is not limited by the accompanying drawings and all changes, equivalents, or substitutes included in the spirit and the technical scope of the present disclosure are included. In the drawings, the components may be exaggeratedly large or small in size or thickness for convenience of understanding and the like, but the protection scope of the present disclosure should not be construed as being limited thereto.

Terms used in this specification are used only to describe specific implementation example or embodiments, and are not intended to limit the present disclosure. In addition, the singular expressions may include a plural expressions unless the context clearly dictates otherwise. The terms “include,” “consist of,” and the like in the specification are intended to designate the presence of features, numbers, steps, operations, components, parts, or combinations thereof described in the specification. That is, terms such as “comprise,” “consist of,” and the like in the specification should be understood as not precluding the presence or addition of one or more other features, numbers, steps, operations, elements, parts, or combinations thereof.

Terms including ordinal numbers such as first, second, and the like may be used to describe various elements, but the elements are not limited by such terms. These terms are used only for the purpose of distinguishing one element from another.

When an element is referred to as being “connected” or “coupled” to another element, it may be directly connected or coupled to the other element, or intervening elements may be present. On the other hand, when an element is referred to as being “directly connected” or “directly coupled” to another element, it should be understood that no intervening elements are present.

When a component is referred to as being “above” or “below” another component, it should be understood that the component may be disposed not only directly on or under the other component, but also that other components may exist therebetween.

Unless otherwise defined, all terms used herein, including technical or scientific terms, have the same meaning as commonly understood by those skilled in the art to which the present disclosure pertains. Terms such as those defined in commonly used dictionaries are to be interpreted as having a meaning that is consistent with their meaning in the context of the relevant art and are not to be interpreted in an idealized or overly formal sense unless expressly so defined herein.

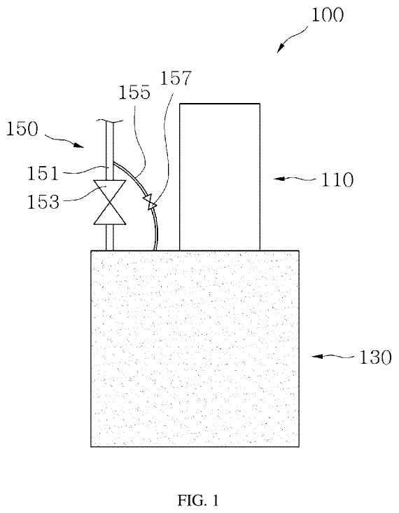

FIG. 1 is a conceptual diagram illustrating a substrate processing apparatus according to an embodiment of the present disclosure.

Referring to the drawing, the substrate processing apparatus 100 may include a process chamber 110, a load-lock chamber 130, and an exhaust module 150.

The process chamber 110 may include a reaction space for accommodating a substrate. To reduce concerns about contamination of the substrate, a portion defining the reaction space may be made of a non-metallic material, for example, quartz. A temperature of the reaction space may reach several hundred to one thousand degrees Celsius or higher, depending on an operation of a heater. The substrate may be, for example, a semiconductor wafer loaded on a boat. The substrate is not limited to the wafer, and other base structures for making circuits are also possible. For example, the substrate may also include glass for display fabrication.

Reaction gases such as hydrogen gas (H₂), deuterium gas (D₂), fluorine gas (F₂), ammonia gas (NH₃), chlorine gas (Cl₂), nitrogen gas (N₂), and the like may be selectively injected into the reaction space. When a protective space accommodating the reaction space is provided, a protective gas such as an inert gas, for example, nitrogen gas or argon gas (Ar), may be injected into the protective space. The protective gas is specifically supplied to a protective region of the protective space excluding the reaction space.

The inert gas may be injected into the reaction space or the protective space as a cooling gas, purge gas, cleaning gas, etc., depending on an operating mode of the process chamber 110. The reaction gas and the protective gas, and further the cooling gas, may be simply referred to as process gas.

The process gas may reach a pressure higher than an atmospheric pressure (high pressure), e.g., from several atmospheres to tens of atmospheres, within the reaction space and the protective space. When the pressure in the reaction space is a first pressure and the pressure in the protective space is a second pressure, the first pressure and the second pressure may be maintained in a set relationship (pressure difference). For example, the second pressure may be set substantially the same as or somewhat greater than the first pressure. Such a pressure relationship provides an advantage of preventing the reaction gas from leaking from the reaction space.

The load-lock chamber 130 may have a hollow housing having an accommodation space. With the boat moved from the reaction space into the accommodation space, the substrate may be loaded into the boat or unloaded from the boat. The boat may move to the reaction space with a new substrate loaded therein again, and the substrate may be processed in the reaction space while loaded in the boat. The boat may be mounted on a door or an endcap, which is a portion defining the reaction space, and may move together with the door.

Gas may be injected into the load-lock chamber 130. The gas may include a purge gas and a venting gas, and they may be inert gases. While the purge gas is for preventing oxidation of the substrate located within the load-lock chamber 130, the venting gas may be for increasing the gas pressure inside the load-lock chamber 130. The gas in the load-lock chamber 130 may also include fumes expelled from the substrate. Hereinafter, all gases present in the load-lock chamber 130, specifically the purge gas, the venting gas the fumes, and the like are collectively referred to as the load-lock gas.

The exhaust module 150 is configured to exhaust the load-lock gas from the load-lock chamber 130. The exhaust module 150 may include a main exhaust line 151 and a sub-exhaust line 155.

The main exhaust line 151 provides a passage through which most of the load-lock gas flows out during exhaustion of the load-lock chamber 130. The main exhaust line 151 is connected to a vacuum pump, enabling the load-lock chamber 130 to reach a vacuum state.

One end of the sub-exhaust line 155 is also connected to the load-lock chamber 130, providing a passage for the load-lock gas to flow out from the load-lock chamber 130. The other end of the sub-exhaust line 155 may be connected to the main exhaust line 151. Specifically, the sub-exhaust line 155 may be connected to a rear of a main flow control valve 153 of the main exhaust line 151, which will be described later.

The sub-exhaust line 155 allows the load-lock gas to be exhausted at a lower flow rate compared to the main exhaust line 151. To this end, an inner diameter of the sub-exhaust line 155 may be half or less of an inner diameter of the main exhaust line 151, and more preferably, the former may be within a range of 5% to 15% of the latter. If the former is less than 5% of the latter, it may be difficult to stabilize the gas pressure of the load-lock chamber 130 even when exhausting the load-lock gas through both the main exhaust line 151 and the sub-exhaust line 155. If the former exceeds 15% of the latter, the exhaust of the load-lock gas through the sub-exhaust line 155 may rather intensify fluctuations in the gas pressure of the load-lock chamber 130. If the former exceeds 15% of the latter, an exhaust volume through the sub-exhaust line 155 may be controlled through valves or orifices installed in the sub-exhaust line 155, but there is little need to do so when the former exceeds 50% of the latter.

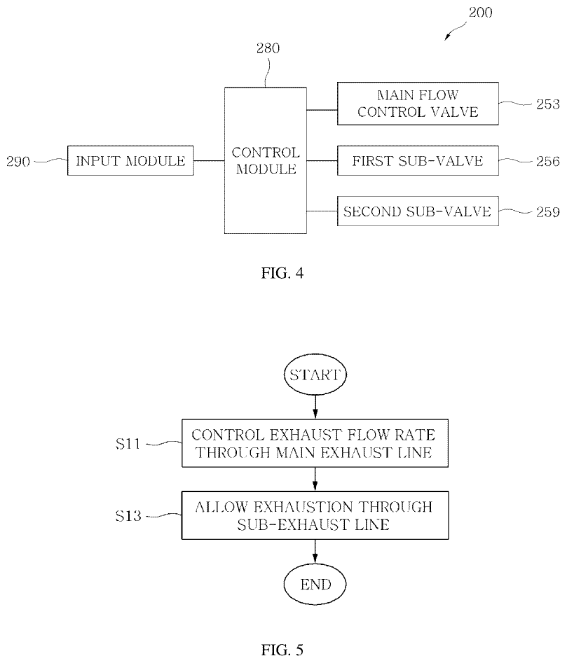

The main flow control valve 153 may be installed in the main exhaust line 151. An opening degree of the main flow control valve 153 may be adjusted according to control signals from a control module 280 (see FIG. 4). Even while the opening degree of the main flow control valve 153 is being adjusted, the exhaust of the load-lock gas through the sub-exhaust line 155 may still be in progress.

A sub-flow control valve 157 may also be installed in the sub-exhaust line 155. Since the sub-flow control valve 157 is not controlled by the control module, the opening degree of the sub-flow control valve 157 may be maintained at a set value.

According to such a configuration, within a range where the adjustment of the opening degree of the main flow control valve 153 is not turning off the main flow control valve 153, the load-lock gas may be exhausted in parallel through the main exhaust line 151 and the sub-exhaust line 155. By exhausting the load-lock gas through the sub-exhaust line 155 as well, the gas pressure in the load-lock chamber 130 may be stably controlled even with a response delay of the main flow control valve 153.

Furthermore, since the sub-flow control valve 157 is a mechanical valve that operates in the state set by an operator as it is and does not require separate additional control, control of the exhaust module 150 may be simplified.

Additionally, since the sub-exhaust line 155 is connected to the main exhaust line 151, there is no need to connect a separate vacuum pump to the sub-exhaust line 155.

In an alternative embodiment, the sub-exhaust line 155 may be connected to an exhaust structure other than the main exhaust line 151. The other exhaust structure may be in communication with a vacuum pump. In that case, a portion of the load-lock gas may be exhausted through the sub-exhaust line 155 and the other exhaust structure.

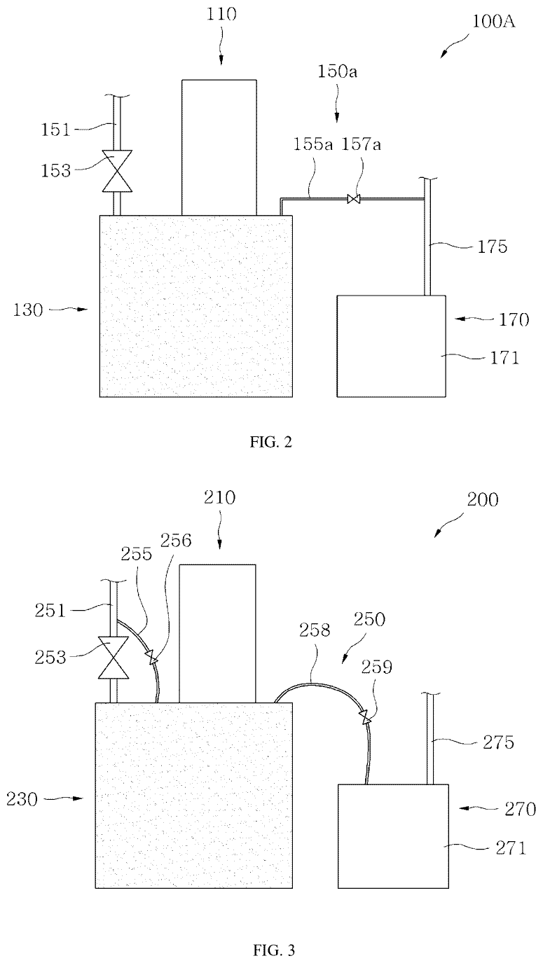

FIG. 2 is a conceptual diagram illustrating a substrate processing apparatus according to a modified example of the substrate processing apparatus of FIG. 1.

Referring to the drawing, a substrate processing apparatus 100A is substantially the same as the substrate processing apparatus 100 (see FIG. 1) according to the previous embodiment, but differs in that a sub-exhaust line 155a of an exhaust module 150a is connected to a box exhaust line 175 of a gas box 170.

The gas box 170 is configured to supply the process gas to the process chamber 110 and exhaust the process gas from the process chamber 110. For this purpose, various piping, valves, flow meters, and the like may be present within the case 171 of the gas box 170.

In response to gas leakage from the piping, the valve, and the flow meter, an inert gas may be injected into the case 171 or external air may be introduced therein. The external air or the inert gas may be exhausted through the box exhaust line 175. A vacuum pump connected to the box exhaust line 175 may generate a flow that exhausts the gas present within the case 171 through the box exhaust line 175.

In the embodiment as well, the main flow control valve 153 may be installed in the main exhaust line 151, and the sub-flow control valve 157a may be installed in the sub-exhaust line 155a.

According to such a configuration, the sub-exhaust line 155a may also perform a role of exhausting the load-lock gas together with the main exhaust line 151. Additionally, since the sub-exhaust line 155a is connected to the box exhaust line 175, there is no need to connect a separate vacuum pump to the sub-exhaust line 155a. Furthermore, since the exhaust flow rate of the sub-exhaust line 155a may be set separately from the exhaust flow rate through the main exhaust line 151, the exhaust flow rate of the sub-exhaust line 155a is not affected thereby even in a situation where the load-lock gas is exhausted from the main exhaust line 151, so that a pressure control function of the sub-exhaust line 155a may become more accurate.

In an alternative embodiment, the sub-exhaust line may be connected to the case 171 other than the box exhaust line 175. Even in this case, since an internal space of the case 171 is in communication with the sub-exhaust line 155a, a separate vacuum pump for the sub-exhaust line is unnecessary.

FIG. 3 is a conceptual diagram illustrating a substrate processing apparatus according to another embodiment of the present disclosure.

Referring to the drawing, the substrate processing apparatus 200 is substantially the same as the substrate processing apparatus 100A according to the modified example, but differs in the sub-exhaust line and the sub-flow control valve of the exhaust module 250.

The sub-exhaust line may include a first sub-line 255 and a second sub-line 258. The first sub-line 255 may be connected to a main exhaust line 251, and the second sub-line 258 may be connected to a case 271 of a gas box 270.

The main flow control valve 253 may be installed in the main exhaust line 251, and the sub-flow control valve may also be installed in the sub-exhaust line. The sub-flow control valve may be an electronic valve controlled by a control module 280 (see FIG. 4), like the main flow control valve 253.

The sub-flow control valve may include a first sub-valve 256 and a second sub-valve 259. The first sub-valve 256 may control the exhaust of the load-lock gas through the first sub-line 255, and the second sub-valve 259 may control the exhaust of the load-lock gas through the second sub-line 258.

When a pressure difference between the load-lock chamber 230 and the case 271 is small, or when the pressure of the case 271 is higher than that of the load-lock chamber 230, a pump (not illustrated) may be additionally installed in the second sub-line 258 to prevent backflow of the load-lock gas.

In an alternative embodiment, the first sub-line 255 may be connected to the box exhaust line 275 of the gas box 270.

FIG. 4 is a block diagram for describing a control operation of the substrate processing apparatus of FIG. 3.

Referring to the drawing (and FIG. 3), operations of the main flow control valve 253, the first sub-valve 256, and the second sub-valve 259 may be controlled by the control module 280. The control module 280 is a computing device, and a program for the operation may be recorded on a computer-readable recording medium. Examples of the computer-readable recording medium include a hard disk, compact disk, flash memory, flexible disk, memory card, and the like.

To control the main flow control valve 253 and the like, the control module 280 may receive related information from an input module 290. The input module 290 may be, for example, a sensor detecting the position of the boat. The control module 280 may, based on an input from the sensor, determine whether the boat is located in the load-lock chamber 230 and, based thereon, cause the opening degree of the main flow control valve 253 to be adjusted. As a result, the gas pressure of the load-lock chamber 230 may be controlled under the control of the control module 280.

The control module 280 may adjust the opening degree of the main flow control valve 253 and selectively open either of the first sub-valve 256 or the second sub-valve 259. For example, the control module 280 may open the first sub-valve 256 when the boat is located in the load-lock chamber 230 and open the second sub-valve 259 when the boat is located in the process chamber 210. In the latter case, the control module 280 may operate the pump installed in the second sub-line 258.

According to such a configuration, depending on the state of the load-lock gas present within the load-lock chamber 230, the load-lock gas may be discharged through the main exhaust line 251 or the box exhaust line 275, or may act as a purge gas in the case 271.

In the latter case, the load-lock gas serves to purge the gas present within the case 271, thereby enabling reduction of the amount of purge gas to be injected into the case 271. Furthermore, even if the external air is introduced into the case 271, the load-lock gas (mainly inert gas) may assist in suppressing a combustion reaction in the case 271 by lowering the oxygen concentration in the external air.

Moreover, only when the boat is not located in the load-lock chamber 230, when the second sub-valve 259 is opened, the load-lock gas may be supplied to the case 271 in a cleaner state without fumes from the substrate. Thus, the load-lock gas may minimize a possibility of deteriorating a quality of the gas in the case 271.

FIG. 5 is a flowchart showing a gas pressure control method in a substrate processing apparatus according to yet another embodiment of the present disclosure.

Referring to the drawing (and FIGS. 1 to 4), in order to control the gas pressure within the substrate processing apparatus, specifically within the load-lock chamber, the control module 280 may control exhaust flow rates of the load-lock gas through the main exhaust lines 151 and 251 by adjusting the opening degrees of the main flow control valves 153 and 253 (S11). Since vacuum pumps connected to the main exhaust lines 151 and 251 are operating, the exhaust flow rate of the load-lock gas may be varied merely by changing the opening degree.

During the adjustment of the opening degree, the control module 280 may allow the exhaust of the load-lock gas through the sub-exhaust lines 155, 155a, 255, and 258 (S13). The control module 280 may not control mechanical sub-flow control valves 157 and 157a, but may cause either the electronic sub-flow control valves 256 and 259 to be opened or the other to be closed, so that the load-lock gas is exhausted through the sub-exhaust lines 155, 155a, 255, and 258 in a lesser amount than an exhaust amount through the main exhaust lines 151 and 251.

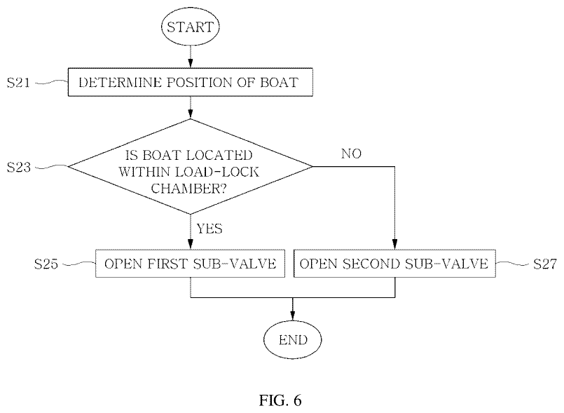

FIG. 6 is a flowchart showing specific contents of one step of FIG. 5.

Referring to the drawing (and FIGS. 3 and 4), a specific content of an exhaust allowance step S13 (see FIG. 5) through the sub-exhaust line is described.

The control module 280 may determine the position of the boat through the input module 290 (S21). The boat may be located within the reaction space or within the load-lock chamber 230.

When the boat is located inside the load-lock chamber 230 (S23), the control module 280 may open the first sub-valve 256 and close the second sub-valve 259 (S25). In that case, the load-lock gas is not provided to the case 271 of the gas box 270 and is exhausted through the main exhaust line 251 or the box exhaust line 275 (first mode).

Conversely, when the boat is located within the reaction space other than the load-lock chamber 230 (S23), the control module 280 may open the second sub-valve 259 and close the first sub-valve 256. In such a case, the load-lock gas may be supplied to the case 271 of the gas box 270 (second mode) and may perform the role of the purge gas within the case 271.

According to such a configuration, in the second mode, the load-lock gas is not simply discarded but is reused as appropriate quality of purge gas within the case 271, thereby increasing the gas usage efficiency of the substrate processing apparatus.

Furthermore, the control module 280 may switch from the first mode to the second mode only after the boat has left the load-lock chamber 230 and a certain amount of time has elapsed. In such a case, a purity of the load-lock gas may be higher.

What is claimed is:

1. A substrate processing apparatus comprising:
a process chamber accommodating a boat for loading a substrate;
a load-lock chamber configured to accommodate a boat moved from the process chamber; and
an exhaust module having a main exhaust line connected to the load-lock chamber to exhaust a load-lock gas present in the load-lock chamber, and a sub-exhaust line connected to the load-lock chamber and configured to exhaust the load-lock gas at a lower flow rate than the main exhaust line.

2. The substrate processing apparatus of claim 1, wherein an inner diameter of the sub-exhaust line is half or less than an inner diameter of the main exhaust line.

3. The substrate processing apparatus of claim 1, wherein the exhaust module further includes a main flow control valve installed in the main exhaust line, and
further includes a control module configured to adjust an opening degree of the main flow control valve by controlling the main flow control valve, and
the control module is configured to adjust the opening degree while the load-lock gas is exhausted through the sub-exhaust line.

4. The substrate processing apparatus of claim 3, wherein the control module is configured to control the main flow control valve to allow the load-lock gas to be exhausted through the main exhaust line and the sub-exhaust line in parallel.

5. The substrate processing apparatus of claim 3, wherein the exhaust module further includes a sub-flow control valve installed in the sub-exhaust line, and
an opening degree of the sub-flow control valve is maintained at a set value.

6. The substrate processing apparatus of claim 1, wherein the sub-exhaust line is connected to any one selected from the group consisting of the main exhaust line, a case of a gas box for supplying process gas to the process chamber, and a box exhaust line connected to the case for exhausting box gas within the case.

7. The substrate processing apparatus of claim 6, wherein the sub-exhaust line includes
a first sub-line connected to either the main exhaust line or the box exhaust line, and
a second sub-line connected to the case, and
the exhaust module further includes
a first sub-valve installed in the first sub-line, and
a second sub-valve installed in the second sub-line, and
further includes a control module configured to control the first sub-valve and the second sub-valve.

8. The substrate processing apparatus of claim 7, wherein the control module is configured to selectively open either the first sub-valve or the second sub-valve.

9. The substrate processing apparatus of claim 8, wherein the control module is configured to open the first sub-valve when the boat is located within the load-lock chamber, and open the second sub-valve when the boat is located within the process chamber.

10. A gas pressure control method in a substrate processing apparatus, comprising:
controlling, to control a pressure of a load-lock gas present in a load-lock chamber accommodating a boat moved from a process chamber, an opening degree of a main flow control valve installed in a main exhaust line connected to the load-lock chamber; and
allowing the load-lock gas to be exhausted at a lower flow rate than the main exhaust line through a sub-exhaust line connected to the load-lock chamber during the adjustment of the opening degree of the main flow control valve.

11. The gas pressure control method in a substrate processing apparatus of claim 10, wherein the allowing of the load-lock gas to be exhausted at the lower flow rate than the main exhaust line through the sub-exhaust line connected to the load-lock chamber during the adjustment of the opening degree of the main flow control valve includes
allowing one mode of the following to be performed:
a first mode to allow the load-lock gas to be exhausted through either the main exhaust line or a box exhaust line of a gas box for supplying a process gas to the process chamber; and
a second mode to allow the load-lock gas to be exhausted through a case of the gas box.

12. The gas pressure control method in a substrate processing apparatus of claim 11, wherein the first mode is performed when the boat is located within the load-lock chamber, and the second mode is performed when the boat is located within the process chamber.
